(19) United States
(12) Patent Application Publication
(10) Pub. No.: US 2016/0181454 A1
(43) Pub. Date: Jun. 23, 2016

(54) SOLAR CELL MODULE AND METHOD FOR MANUFACTURING THE SAME

(71) Applicant: LG ELECTRONICS INC., Seoul (KR)

(72) Inventors: Jeonghun SON, Seoul (KR); Kangseok MOON, Seoul (KR); Kwangyoung LIM, Seoul (KR); Sehwon AHN, Seoul (KR)

(73) Assignee: LG ELECTRONICS INC., Seoul (KR)

(21) Appl. No.: 14/978,905

(22) Filed: Dec. 22, 2015

(30) Foreign Application Priority Data
Dec. 22, 2014 (KR) 10-2014-0186536

(51) Int. Cl. H01L 31/05; H01L 31/0224; H01L 31/18; H01L 31/048

(52) U.S. Cl. CPC H01L 31/0504; H01L 31/048; H01L 31/0481; H01L 31/022441; H01L 31/18

(57) ABSTRACT

A solar cell module and a method for manufacturing the same are discussed. The solar cell module includes a front transparent substrate and a back substrate positioned opposite each other, a plurality of solar cells positioned between the front transparent substrate and the back substrate, each solar cell including a semiconductor substrate and first and second electrodes, the first and second electrodes being separated from each other on a back surface of the semiconductor substrate and each extending in a first direction, a first conductive line connected to the first electrode included in the each solar cell through a conductive adhesive, a second conductive line connected to the second electrode included in the each solar cell through the conductive adhesive, a first encapsulant positioned between the solar cells and the front transparent substrate, and a second encapsulant positioned between the solar cells and the back substrate.

### CROSS-REFERENCE TO RELATED APPLICATION

This application claims priority to and the benefit of Korean Patent Application No. 10-2014-0186536 filed in the Korean Intellectual Property Office on Dec. 22, 2014 the entire contents of which are incorporated herein by reference.

### BACKGROUND OF THE INVENTION

1. Field of the Invention

Embodiments of the invention relate to a solar cell module and a method for manufacturing the same.

2. Description of the Related Art

A solar cell generally includes a substrate and an emitter region, which are formed of semiconductors of different conductive types, for example, a p-type and an n-type, and electrodes respectively connected to the substrate and the emitter region. A p-n junction is formed at an interface between the substrate and the emitter region.

The solar cell using the semiconductor substrate may be classified into a conventional solar cell and a back contact solar cell depending on a structure.

The conventional solar cell is configured such that an emitter region is positioned on a front surface of a substrate, an electrode connected to the emitter region is positioned on the front surface of the substrate, and an electrode connected to the substrate is positioned on a back surface of the substrate. The back contact solar cell is configured such that an emitter region is positioned on a back surface of a substrate, and all of electrodes are positioned on the back surface of the substrate.

Because all of the electrodes of the back contact solar cell are formed on the back surface of the substrate, the electrodes formed on the back surface of the substrate are connected in series to electrodes of an adjacent solar cell through an interconnector or a separate conductive metal. Hence, a solar cell module may be manufactured.

### SUMMARY OF THE INVENTION

In one aspect, there is a solar cell module including a front transparent substrate and a back substrate positioned opposite each other, a plurality of solar cells positioned between the front transparent substrate and the back substrate, each solar cell including a semiconductor substrate and first and second electrodes, the first and second electrodes being separated from each other on a back surface of the semiconductor substrate and each extending in a first direction, a first conductive line connected to the first electrode included in the each solar cell through a conductive adhesive, a second conductive line connected to the second electrode included in the each solar cell through the conductive adhesive, a first encapsulant of an insulating material positioned between the plurality of solar cells and the front transparent substrate, and a second encapsulant of an insulating material positioned between the plurality of solar cells and the back substrate, wherein the second encapsulant is filled in a space between the first electrode of the each solar cell and the second conductive line and a space between the second electrode of the each solar cell and the first conductive line.

The second encapsulant may be further filled in a space between the first electrode and the second electrode in the each solar cell.

The first and second conductive lines may be separated from each other and each of the first and second conductive lines may extend in a second direction crossing the first direction.

A thickness of the conductive adhesive may be greater than a thickness of each of the first and second electrodes. A thickness of each of the first and second conductive lines may be greater than the thickness of the conductive adhesive.

For example, the thickness of the each of the first and second electrodes may be 0.2 μm to 1 μm, the thickness of the conductive adhesive may be 50 μm to 150 μm, and the thickness of the each of the first and second conductive lines may be 180 μm to 220 μm.

Each of the first and second conductive lines may include a core and a coating layer coated on a surface of the core, and a melting point of the coating layer may be lower than a melting point of the core.

The conductive adhesive may include metal particles having a melting point that is higher than the melting point of the coating layer and is lower than the melting point of the core. For example, the metal particles may include first metal particles having a melting point higher than 160° C. and second metal particles having a melting point higher than the melting point of the first metal particles.

An amount of the first metal particles may be more than an amount of the second metal particles.

The conductive adhesive may includes an intermetallic compound, that is chemically bonded by melting surfaces of the first and second metal particles, between the first and second metal particles.

The melting point of the coating layer may be 110° C. to 160° C.

A melting point of the second encapsulant may be 70° C. to 100° C. The second encapsulant may include at least one of ethylene vinyl acetate (EVA), polyolefin, ionomer, or poly vinyl butyral (PVB).

The plurality of solar cells may include a first solar cell and a second solar cell. A first conductive line connected to a first electrode of the first solar cell and a second conductive line connected to a second electrode of the second solar cell may be positioned between semiconductor substrates of the first and second solar cells and may be connected to an interconnector extending in the first direction.

In another aspect, there is a method for manufacturing a solar cell module including preparing a solar cell, in which first and second electrodes are formed on a back surface of a semiconductor substrate of the solar cell, a conductive adhesive forming operation of applying a conductive adhesive paste on each of the first and second electrodes and curing the conductive adhesive paste through thermal processing to form a conductive adhesive, temporarily bonding a first conductive line including a coating layer having a melting point lower than the cured conductive adhesive to the first electrode and temporarily bonding a second conductive line including a coating layer having a melting point lower than the cured conductive adhesive to the second electrode, a disposition operation of disposing a front transparent substrate on a front surface of the solar cell, disposing a back substrate on a back surface of the solar cell, disposing a first encapsulant between the front transparent substrate and the solar cell, and disposing a second encapsulant between the back substrate and the solar cell, and a lamination operation of, after the disposition operation, performing a pressurization process and a thermal process to fill the second encapsulant between the first and second electrodes.

The lamination operation may include filling the second encapsulant between the first electrode and the second conductive line and between the second electrode and the first conductive line.

The method may further include disposing an interconnector between a first solar cell and a second solar cell that are included in the solar cell and are positioned adjacent to each other. A first conductive line connected to the first solar cell and a second conductive line connected to the second solar cell may be commonly connected to the interconnector.

A temperature of the thermal processing in the conductive adhesive forming operation may be higher than a temperature of the thermal process in the lamination operation.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIGS. 1 to 6 illustrate a solar cell module according to an example embodiment of the invention;

FIGS. 7 and 8 illustrate a structure, in which a plurality of solar cells are connected in series to one another, in a solar cell module according to an example embodiment of the invention;

FIG. 9 is a flow chart showing a first example of a method for manufacturing a solar cell module according to an example embodiment of the invention; and

FIG. 10 is a flow chart showing a second example of a method for manufacturing a solar cell module according to an example embodiment of the invention.

### DETAILED DESCRIPTION OF THE EMBODIMENTS

Reference will now be made in detail to embodiments of the invention, examples of which are illustrated in the accompanying drawings. This invention may, however, be embodied in many different forms and should not be construed as limited to the embodiments set forth herein. Wherever possible, the same reference numbers will be used throughout the drawings to refer to the same or like parts. It should be noted that a detailed description of known arts will be omitted if it is determined that the detailed description of the known arts can obscure the embodiments of the invention.

In the following description, “front surface” may be one surface of a semiconductor substrate, on which light is directly incident, and “back surface” may be a surface opposite the one surface of the semiconductor substrate, on which light is not directly incident or reflective light may be incident.

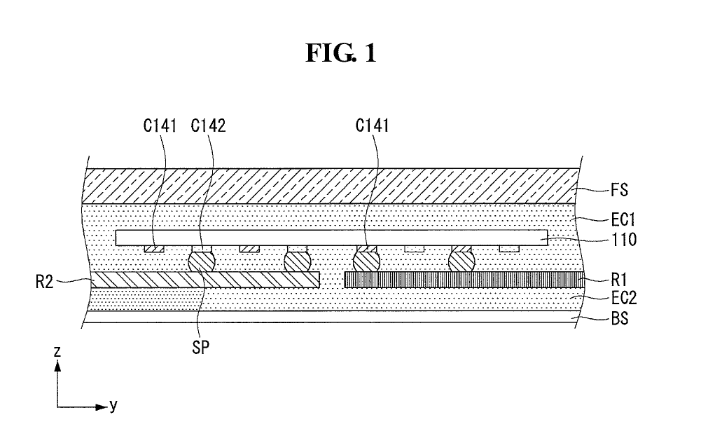

Exemplary embodiments of the invention are described with reference to FIGS. 1 to 10.

FIGS. 1 to 6 illustrate a solar cell module according to an example embodiment of the invention.

More specifically, FIG. 1 illustrates a solar cell module according to an example embodiment of the invention.

As shown in FIG. 1, the solar cell module according to the embodiment of the invention may include a front transparent substrate FS, a first encapsulant EC1, solar cells (represented by a substrate 110), first conductive lines R1, second conductive lines R2, a second encapsulant EC2, and a back substrate BS.

The front transparent substrate FS is formed of a tempered glass having a high transmittance and an excellent damage prevention function. In this instance, the tempered glass may be a low iron tempered glass containing a small amount of iron. The front transparent substrate FS may have an embossed inner surface, so as to increase a scattering effect of light.

The back substrate BS may be positioned opposite the front transparent substrate FS and may be positioned on a back surface of the second encapsulant EC2.

Thus, the back substrate BS prevents moisture and oxygen from penetrating into back surfaces of the solar cells, thereby protecting the solar cells from an external environment. The back substrate BS may have a multi-layered structure including a moisture/oxygen penetrating prevention layer, a chemical corrosion prevention layer, etc.

The back substrate BS may be formed using a thin insulating sheet formed of an insulating material such as fluoropolymer/polyester/fluoropolymer (FP/PE/FP). The back substrate BS may be formed of the tempered glass in the same manner as the front transparent substrate FS.

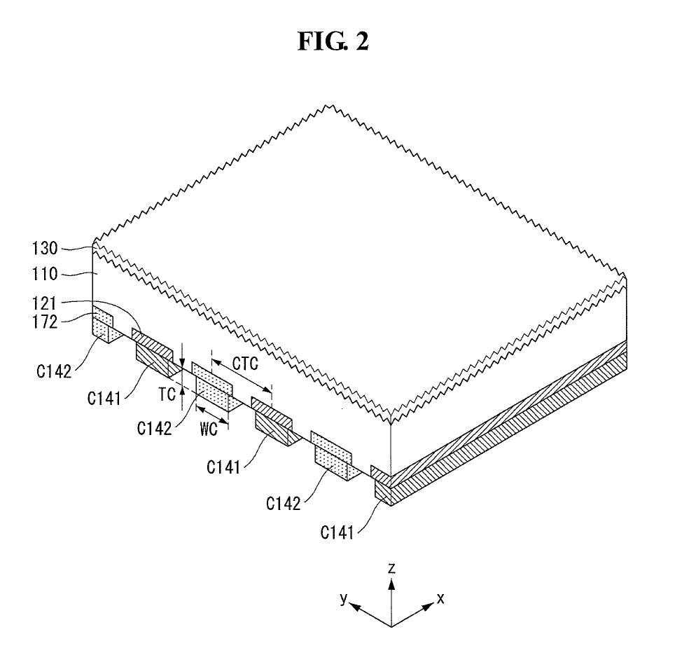

As shown in FIG. 1, the solar cells may be positioned between the front transparent substrate FS and the back substrate BS. As shown in FIG. 2, each solar cell may include a semiconductor substrate 110 and first and second electrodes C141 and C142 which are positioned on a back surface of the semiconductor substrate 110 and are separated from each other.

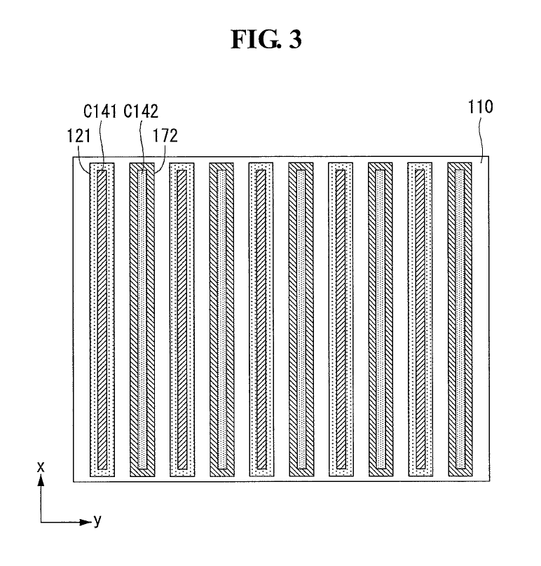

In the embodiment of the invention, each of the first and second electrodes C141 and C142 may be in the plural. Although longitudinal directions of the first and second electrodes C141 and C142 are not clearly shown, the first and second electrodes C141 and C142 may extend in a first direction x. Patterns of the first and second electrodes C141 and C142 will be described in detail with reference to FIGS. 2 and 3 after an entire structure of the solar cell module is briefly described.

The first conductive lines R1 are connected to the first electrodes C141 included in each solar cell through a conductive adhesive SP, and the second conductive lines R2 are connected to the second electrodes C142 included in each solar cell through the conductive adhesive SP.

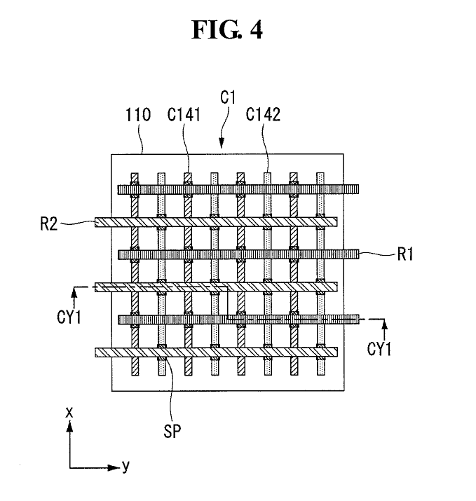

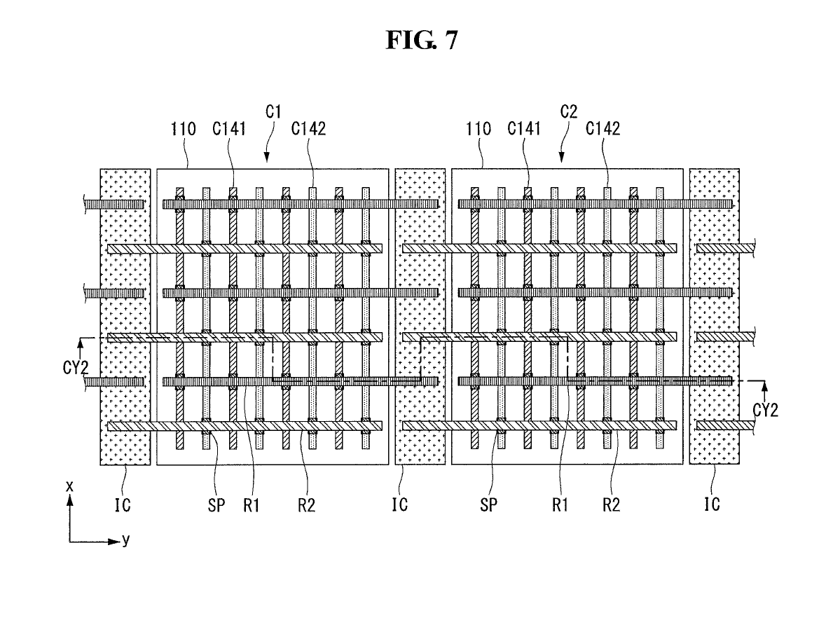

The first and second conductive lines R1 and R2 may be separated from each other and may extend in a second direction y crossing the first direction x. In FIG. 1, the first and second conductive lines R1 and R2 are shown as if they are separated from each other in a state where each of the first and second conductive lines R1 and R2 is disposed on about a half of the semiconductor substrate 110. However, the first and second conductive lines R1 and R2 are conceptually shown in FIG. 1. In fact, the first and second conductive lines R1 and R2 may be connected to a back surface of each solar cell in a pattern shown in FIGS. 4 and 7.

Further, only one solar cell is shown in FIG. 1. However, the plurality of solar cells may be positioned between the front transparent substrate FS and the back substrate BS. The first and second conductive lines R1 and R2 connected to each of the plurality of solar cells may be connected to an interconnector and may connect the plurality of solar cells in series in the second direction y.

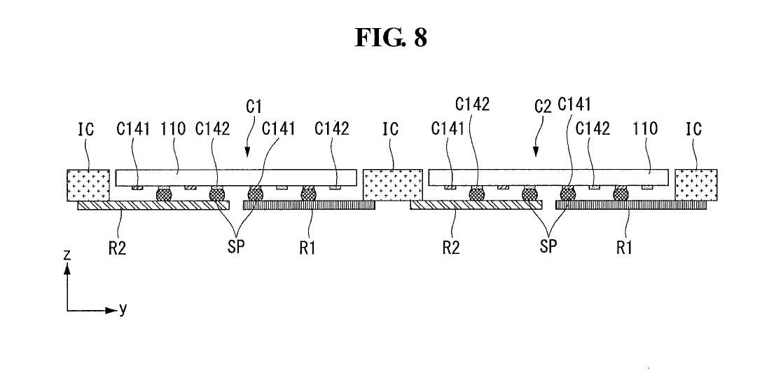

A structure, in which the plurality of solar cells are connected to each other through the interconnector, is described in detail below with reference to FIGS. 7 and 8.

The first encapsulant EC1 may be disposed between the solar cells and the front transparent substrate FS, and the second encapsulant EC2 may be disposed between the back substrate BS and the solar cells.

The first and second encapsulants EC1 and EC2 may be integrated with the solar cells through a lamination process in a state where the first and second encapsulants EC1 and EC2 are respectively disposed on and under the solar cells and may be cured through thermal processing during the lamination process. The first and second encapsulants EC1 and EC2 can prevent corrosion resulting from the moisture penetration and protect the solar cells from an impact.

The first and second encapsulants EC1 and EC2 may be formed of an insulating material having a melting point of 70° C. to 100° C. For example, the first and second encapsulants EC1 and EC2 may be formed of a material having a volume resistance of 10¹¹ Ωcm to 10¹⁶ Ωcm. More specifically, the first and second encapsulants EC1 and EC2 may be formed using at least one of ethylene vinyl acetate (EVA), polyolefin, ionomer, or poly vinyl butyral (PVB).

The first and second encapsulants EC1 and EC2 may have a sheet shape before the lamination process. The first and second encapsulants EC1 and EC2 may be melted in the lamination process and may be attached to the plurality of solar cells.

As shown in FIG. 1, the solar cell module according to the embodiment of the invention may fill the second encapsulant EC2 in a space between the first electrode C141 and the second conductive line R2 and a space between the second electrode C142 and the first conductive line R1.

Namely, in the lamination process, the first and second encapsulants EC1 and EC2 may be melted by a thermal pressurization process applied when the lamination process is performed. In this instance, the second encapsulant EC2 may be diffused and filled in a space between the first electrode C141 and the second conductive line R2 and a space between the second electrode C142 and the first conductive line R1.

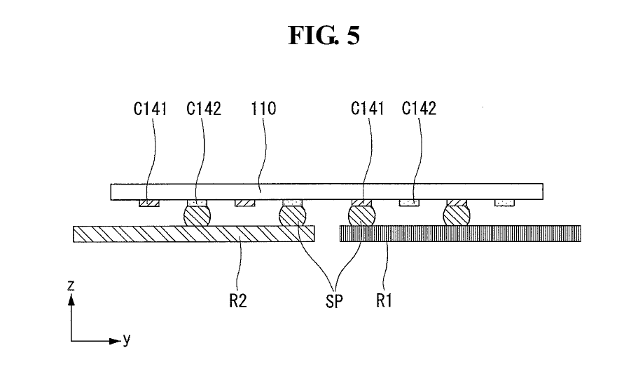

In the embodiment disclosed herein, the space between the first electrode C141 and the second conductive line R2 indicates a space formed by overlapping the first electrode C141 and the second conductive line R2 when viewed from the back surface of the solar cell module as shown in FIG. 4 and also by separating the first electrode C141 and the second conductive line R2 from each other when viewed at the cross-section of the solar cell module as shown in FIGS. 1 and 5.

Further, the space between the second electrode C142 and the first conductive line R1 indicates a space formed by overlapping the second electrode C142 and the first conductive line R1 when viewed from the back surface of the solar cell module as shown in FIG. 4 and also by separating the second electrode C142 and the first conductive line R1 from each other when viewed at the cross-section of the solar cell module as shown in FIGS. 1 and 5.

Further, the second encapsulant EC2 may be filled in a space between the first and second electrodes C141 and C142 of each solar cell and a space between the first conductive line R1 and the second conductive line R2.

In the embodiment disclosed herein, the space between the first and second electrodes C141 and C142, as shown in FIG. 1, indicates a space formed by the side of the first electrode C141, the side of the second electrode C142, and the back surface of the semiconductor substrate 110.

Hence, the solar cell module according to the embodiment of the invention does not have to include a separate insulating layer for preventing a short circuit between the first conductive line R1 and the second electrode C142 and a short circuit between the second conductive line R2 and the first electrode C141. As a result, the manufacturing process of the solar cell module can be further simplified.

Hereinafter, an example of a solar cell applicable to the solar cell module shown in FIG. 1 is described. However, the embodiment of the invention is not limited to the solar cell, which will be described below.

FIG. 2 is a partial perspective view showing an example of a solar cell applied to the solar cell module shown in FIG. 1, and FIG, 3 shows a back pattern of first and second electrodes of the solar cell shown in FIG. 2.

As shown in FIGS. 2 and 3, an example of a solar cell according to the embodiment of the invention may include a semiconductor substrate 110, an anti-reflection layer 130, a plurality of emitter regions 121, a plurality of back surface field (BSF) regions 172, a plurality of first electrode C141, and a plurality of second electrodes 142.

The anti-reflection layer 130 and the back surface field region 172 may be omitted, if necessary or desired. In the following description, the embodiment of the invention describes the solar cell including the anti-reflection layer 130 and the back surface field region 172 as shown in FIGS. 2 and 3, as an example.

The semiconductor substrate 110 may be a semiconductor substrate formed of silicon of a first conductive type, for example, an n-type, though not required. The semiconductor substrate 110 may be formed by doping a semiconductor wafer formed of crystalline silicon with impurities of the first conductive type, for example, n-type impurities.

The plurality of emitter regions 121 may be positioned to be separated from one another inside a back surface opposite a front surface of the semiconductor substrate 110 and may extend in the first direction x parallel to one another. The plurality of emitter regions 121 may contain impurities of a second conductive type (for example, p-type) opposite the first conductive type (for example, n-type) of the semiconductor substrate 110.

Thus, the emitter regions 121 may form a p-n junction along with the semiconductor substrate 110.

The plurality of back surface field regions 172 may be positioned to be separated from one another inside the back surface of the semiconductor substrate 110 and may extend in the first direction x parallel to the plurality of emitter regions 121. Thus, as shown in FIGS. 2 and 3, the plurality of emitter regions 121 and the plurality of back surface field regions 172 may be alternately positioned at the back surface of the semiconductor substrate 110.

Each back surface field region 172 may be a region (for example, an n⁺⁺-type region) which is more heavily doped than the semiconductor substrate 110 with impurities of the same conductive type as the semiconductor substrate 110.

For reference, the emitter regions 121 and the back surface field regions 172 were omitted in FIGS. 1 and 4 for the sake of brevity and ease of reading.

The plurality of first electrodes C141 may be physically and electrically connected to the plurality of emitter regions 121, respectively, and may be formed on the back surface of the semiconductor substrate 110 along the emitter regions 121.

Further, the plurality of second electrodes C142 may be physically and electrically connected to the semiconductor substrate 110 through the plurality of back surface field regions 172 and may be formed on the back surface of the semiconductor substrate 110 along the plurality of back surface field regions 172.

As shown in FIG. 3, the plurality of first electrodes C141 may extend in the first direction x and may be separated from one another in the second direction y crossing the first direction x.

Further, as shown in FIG. 3, the plurality of second electrodes C142 may extend in the first direction x and may be separated from one another in the second direction y crossing the first direction x.

The plurality of first and second electrodes C141 and C142 may be separated from each other and electrically isolated from each other. The plurality of first and second electrodes C141 and C142 may be alternately positioned on the back surface of the semiconductor substrate 110.

A ratio of a thickness TC to a width WC in each of the first and second electrodes C141 and C142 may be 1:200 to 1:1500. For example, the thickness TC of each of the first and second electrodes C141 and C142 may be 0.2 μm to 1 μm, and the width WC of each of the first and second electrodes C141 and C142 may be 200 μm to 300 μm.

As described above, when the ratio of the thickness TC to the width WC in each of the first and second electrodes C141 and C142 is 1:200 to 1:1500, the manufacturing cost of the solar cell may be minimized.

A distance CTC between a center of the first electrode C141 and a center of the second electrode C142 may be 1 mm to 2 mm. For example, the distance CTC between the center of the first electrode C141 and the center of the second electrode C142 may be 1.5 mm.

In this instance, because a cross-sectional area of each of the first and second electrodes C141 and C142 excessively decreases, a resistance of each of the first and second electrodes C141 and C142 may be a problem. However, the problem of the resistance may be solved by adjusting a number and a width of each of the first and second conductive lines R1 and R2 respectively connected to the first and second electrodes C141 and C142. The plurality of first and second electrodes C141 and C142 may be manufactured through a sputtering method, for example.

In the solar cell according to the embodiment of the invention thus manufactured, holes collected by the first electrodes C141 and electrons collected by the second electrodes C142 may be used as electric power of an external device through an external circuit device.

The solar cell applied to the solar cell module according to the embodiment of the invention is not limited to FIGS. 2 and 3. Other components may be variously changed as long as the first and second electrodes C141 and C142 included in the solar cell are formed on the back surface of the semiconductor substrate 110.

For example, the solar cell module according to the embodiment of the invention may apply a metal wrap through (MWT) solar cell, in which a portion of the first electrode C141 and the emitter region 121 are positioned on the front surface of the semiconductor substrate 110, and the portion of the first electrode C141 on the front surface of the semiconductor substrate 110 is connected to a remaining portion of the first electrode C141 formed on the back surface of the semiconductor substrate 110 through a hole formed in the semiconductor substrate 110.

In the solar cell module including the MWT solar cell, the first and second conductive lines R1 and R2, as described above, may be connected to the first and second electrodes C141 and C142 formed on the back surface of the semiconductor substrate 110.

This is described in detail below with reference to FIGS. 4 to 6.

FIG. 4 shows a back pattern, in which the first and second conductive lines R1 and R2 are connected to the back surface of the solar cell of FIG. 1, and FIG. 5 is a cross-sectional view taken along line CY1-CY1 of FIG. 4.

As shown in FIGS. 4 and 5, the plurality of first conductive lines R1 may be connected to the plurality of first electrodes C141 formed on the back surface of the semiconductor substrate 110 through a conductive adhesive SP, and the plurality of second conductive lines R2 may be connected to the plurality of second electrodes C142 formed on the back surface of the semiconductor substrate 110 through the conductive adhesive SP.

The plurality of first and second conductive lines R1 and R2 may extend in the second direction y crossing the plurality of first and second electrodes C141 and C142 extending in the first direction x.

In this instance, the first and second conductive lines R1 and R2 may be connected to the back surface of the semiconductor substrate 110, so that one end of each of the first and second conductive lines R1 and R2 in the second direction y protrudes further than an end of the semiconductor substrate 110.

Accordingly, as shown in FIGS. 4 and 5, the plurality of first conductive lines R1 may be formed to cross the plurality of first and second electrodes C141 and C142. The plurality of first conductive lines R1 may be connected to the plurality of first electrodes C141 at crossings of the first conductive lines R1 and the first electrodes C141 through the conductive adhesive SP.

Further, as shown in FIGS. 4 and 5, the plurality of second conductive lines R2 may be formed to cross the plurality of first and second electrodes C141 and C142. The plurality of second conductive lines R2 may be connected to the plurality of second electrodes C142 at crossings of the second conductive lines R2 and the second electrodes C142 through the conductive adhesive SP.

In this instance, as shown in FIG. 5, a portion where the first conductive line R1 and the second electrode C142 overlap and cross each other may be separated from a portion where the second conductive line R2 and the first electrode C141 overlap and cross each other. In FIG. 5, the second encapsulant EC2 may be filled in the space between the first electrode C141 and the second conductive line R2 and the space between the second electrode C142 and the first conductive line R1, as described above with reference to FIG. 1.

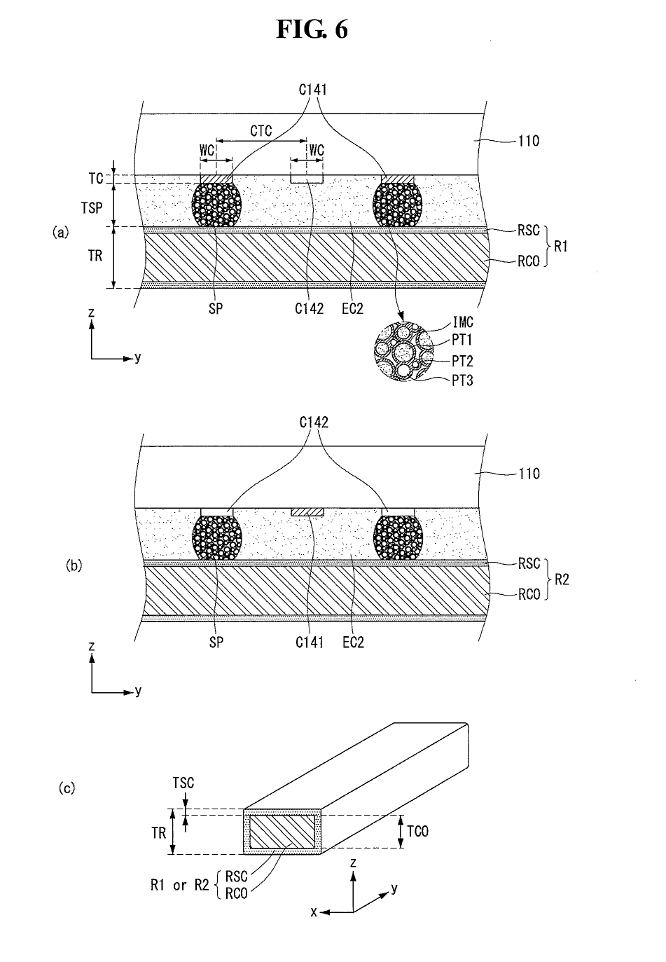

A connection structure of the first conductive line R1 and the first electrode C141 and a connection structure of the second conductive line R2 and the second electrode C142 are described in detail below with reference to FIG. 6.

In FIG. 6, (a) is a cross-sectional view in the second direction y, in which the first conductive line R1 is connected to the first electrode C141, (b) is a cross-sectional view in the second direction y, in which the second conductive line R2 is connected to the second electrode C142, and (c) is a partial perspective view of the first and second conductive lines R1 and R2.

As shown in (a) of FIG. 6, the conductive adhesive SP may be positioned in a portion where the first conductive line R1 extending in the second direction y and the first electrode C141 overlap each other, and the first conductive line R1 and the first electrode C141 may be connected to each other through the conductive adhesive SP. The first conductive line R1 and the second electrode C142 at an overlap location between the first conductive line R1 and the second electrode C142 may be separated from each other by a thickness TSP of the conductive adhesive SP. The second encapsulant EC2 may be filled in a separation space between the first conductive line R1 and the second electrode C142 and may insulate the first conductive line R1 from the second electrode C142.

Further, as shown in (b) of FIG. 6, the conductive adhesive SP may be positioned in a portion where the second conductive line R2 extending in the second direction y and the second electrode C142 overlap each other, and the second conductive line R2 and the second electrode C142 may be connected to each other through the conductive adhesive SP. The second conductive line R2 and the first electrode C141 at an overlap location between the second conductive line R2 and the first electrode C141 may be separated from each other by the thickness TSP of the conductive adhesive SP. The second encapsulant EC2 may be filled in a separation space between the second conductive line R2 and the first electrode C141 and may insulate the second conductive line R2 from the first electrode C141.

In this instance, the thickness TSP of the conductive adhesive SP shown in (a) and (b) of FIG. 6 may be greater than a thickness TC of each of the first and second electrodes C141 and C142. For example, when the thickness TC of each of the first and second electrodes C141 and C142 is 0.2 μm to 1 μm, the thickness TSP of the conductive adhesive SP may be 50 μm to 150 μm.

As described above, when the thickness TSP of the conductive adhesive SP is sufficiently secured, a space between the first conductive line R1 and the second electrode C142 and a space between the second conductive line R2 and the first electrode C141 may be sufficiently secured. Hence, the space between the first conductive line R1 and the second electrode C142 and the space between the second conductive line R2 and the first electrode C141, in which the second encapsulant EC2 will be filled, may be sufficiently provided during the lamination process. As a result, the insulation between the first conductive line R1 and the second electrode C142 and the insulation between the second conductive line R2 and the first electrode C141 may be sufficiently secured.

The conductive adhesive SP may be previously cured before the lamination process in a state where the conductive adhesive SP is applied in a desired portion of each of the first and second electrodes C141 and C142, and the lamination process may be performed at a temperature lower than a curing temperature of the conductive adhesive SP in a state where the conductive adhesive SP is previously cured. Therefore, the lamination process may be performed without a damage of the thickness TSP or a shape of the conductive adhesive SP during the lamination process. Further, the second encapsulant EC2 may be melted during the lamination process and filled in the space between the first conductive line R1 and the second electrode C142 and the space between the second conductive line R2 and the first electrode C141.

In this instance, a temperature of a thermal process for curing the conductive adhesive SP before the lamination process may be 200° C. to 250° C.

In the embodiment disclosed herein, the lamination process is generally performed at 150° C. to 160° C. Therefore, the conductive adhesive SP may include metal particles PT1, PT2, and PT3 each having a melting point higher than 160° C., so that the conductive adhesive SP is not melted during the lamination process. Further, a melting point of the conductive adhesive SP may be higher than a melting point of a coating layer RSC included in each of the first and second conductive lines R1 and R2.

More specifically, the conductive adhesive SP may include metal particles having a melting point higher than the coating layer RSC included in each of the first and second conductive lines R1 and R2.

For example, the conductive adhesive SP may include first metal particles PT1, and a melting point of the first metal particle PT1 may be higher than the melting point of the coating layer RSC included in each of the first and second conductive lines R1 and R2 and may be lower than a melting point of a core RCO included in each of the first and second conductive lines R1 and R2.

For example, the melting point of the first metal particles PT1 may be higher than 160° C. For example, the first metal particles PT1 may be formed of tin (Sn) having a melting point of 232° C.

The conductive adhesive SP may further include second metal particles PT2 having a melting point higher than the melting point of the first metal particles PT1. For example, the second metal particles PT2 may be formed of silver (Ag) having a melting point of 961° C.

The conductive adhesive SP may further include third metal particles PT3 having a melting point higher than the melting points of the first and second metal particles PT1 and PT2. For example, the third metal particles PT3 may be formed of copper (Cu) having a melting point of 1084.6° C.

In the conductive adhesive SP including the first, second, and third metal particles PT1, PT2, and PT3, an amount of the first metal particles PT1 may be more than an amount of the second and third metal particles PT2 and PT3.

As described above, when the amount of the first metal particles PT1 having the relatively low melting point is more than the amount of the second and third metal particles PT2 and PT3, a strength of the conductive adhesive SP may be further improved in the thermal process for curing the conductive adhesive SP, and also the curing temperature of the conductive adhesive SP may be controlled within the above-described range.

Intermetallic compounds IMC, which are chemically bonded by melting the surfaces of the first, second, and third metal particles PT1, PT2, and PT3, may be formed between the first, second, and third metal particles PT1, PT2, and PT3 through the thermal process for curing the conductive adhesive SP. The intermetallic compounds SP may further improve the strength of the conductive adhesive SP and may further improve the melting point of the conductive adhesive SP. In embodiments of the invention, the intermetallic compounds IMC may include some or all of the constituent metals of the first, second, and third metal particles PT1, PT2, and PT3 in definite proportions. In embodiment of the invention, the IMC may be alloys of two or more of the first, second and third metal particles PT1, PT2, and PT3.

For example, the conductive adhesive SP according to the embodiment of the invention may contain 95 wt % to 97 wt % of tin (Sn) forming the first metal particles PT1, 2 wt % to 4 wt % of silver (Ag) forming the second metal particles PT2, and 0.5 wt % to 1 wt % of copper (Cu) forming the third metal particles PT3.

FIG. 6 illustrates that the conductive adhesive SP uses a solder paste, as an example. Unlike this, a conductive adhesive paste, in which metal particles are distributed in an insulating resin, or a conductive adhesive film may be used.

A thickness TR of each of the first and second conductive lines R1 and R2 may be greater than the thickness TSP of the conductive adhesive SP. For example, the thickness TR of each of the first and second conductive lines R1 and R2 may be 180 μm to 220 μm.

Hence, when each of the first and second conductive lines R1 and R2 is connected to the first and second electrodes C141 and C142, the first and second conductive lines R1 and R2 may bend. As a result, the first and second conductive lines R1 and R2 may be prevented from being short-circuited with the first electrode C141 or the second electrode C142.

More specifically, as described above, the distance CTC between the center of the first electrode C141 and the center of the second electrode C142 may be 1 mm to 2 mm, and the width WC of each of the first and second electrodes C141 and C142 may be 200 μm to 300 μm.

For example, in (a) and (b) of FIG. 6, when the distance CTC between the center of the first electrode C141 and the center of the second electrode C142 is 1.5 mm, the width WC of each of the first and second electrodes C141 and C142 is 250 μm, the thickness TC of each of the first and second electrodes C141 and C142 is 1 μm, and the thickness TSP of the conductive adhesive SP is 100 μm, a distance (about 2.75 mm) between the two first electrodes C141 or a distance (about 2.75 mm) between the two second electrodes C142 may be much greater than a sum (about 100 μm) of the thickness TC of each of the first and second electrodes C141 and C142 and the thickness TSP of the conductive adhesive SP.

Accordingly, when the thickness TR of each of the first and second conductive lines R1 and R2 is not sufficiently secured, the first and second conductive lines R1 and R2 may bend and may be short-circuited with the first electrode C141 or the second electrode C142.

However, as shown in (a) of FIG. 6, when the first and second conductive lines R1 and R2 each have the sufficient thickness TR of the above-described range, the first conductive line R1 may bend toward the second electrode C142 positioned between the two first electrodes C141 and may be easily prevented from being short-circuited with the second electrode C142.

Further, as shown in (b) of FIG. 6, the second conductive line R2 may bend toward the first electrode C141 positioned between the two second electrodes C142 and may be easily prevented from being short-circuited with the first electrode C141.

As shown in (c) of FIG. 6, each of the first and second conductive lines R1 and R2 may have a ribbon shape, in which a width is greater than the thickness TR. Alternatively, each of the first and second conductive lines R1 and R2 may have a wire shape, in which a width and a thickness are equal to each other.

Each of the first and second conductive lines R1 and R2 may include the core RCO including conductive metal and the coating layer RSC including conductive metal. The melting point of the core RCO may be higher than the melting point of the conductive adhesive SP and may be higher than 160° C., for example. Further, the melting point of the coating layer RSC may be lower than the melting point of the core RCO and the melting point of the conductive adhesive SP, and may be lower than 160° C., for example.

A thickness TCO of the core RCO may be greater than the thickness TSP of the conductive adhesive SP and may be 180 μm to 220 μm, for example. A thickness TSC of the coating layer RSC may be less than the thickness TSP of the conductive adhesive SP and may be 10 μm to 30 μm, for example.

The conductive metal included in the core RCO may use any metal as long as a melting point is higher than 160° C. For example, copper (Cu) may be used. Further, the conductive metal included in the coating layer RSC may use any metal as long as a melting point is lower than 160° C., is higher than a melting point of the second encapsulant EC2, and is lower than a temperature of the lamination process. For example, the melting point of the coating layer RSC may be 110° C. to 160° C., and the coating layer RSC may be formed of SnIn or SnBi.

The coating layers RSC of the first and second conductive lines R1 and R2 may be melted during the lamination process including the thermal process performed at 150° C. to 160° C. and may be connected to the conductive adhesive SP as shown in (a) and (b) of FIG. 6.

As shown in (a) and (b) of FIG. 6, in the structure in which the first and second conductive lines R1 and R2 are connected to the first and second electrodes C141 and C142 through the conductive adhesive SP, the second encapsulant EC2 may be melted during the lamination process and may be diffused and filled in the separation space between the first conductive line R1 and the second electrode C142 and the separation space between the second conductive line R2 and the first electrode C141.

So far, the embodiment of the invention described the structure, in which the first and second conductive lines R1 and R2 are connected to the back surface of the solar cell applicable to the solar cell module according to the embodiment of the invention. Hereinafter, the embodiment of the invention describes a structure, in which the plurality of solar cells are connected in series.

FIGS. 7 and 8 illustrate a structure, in which a plurality of solar cells are connected in series to one another, in the solar cell module according to the embodiment of the invention.

More specifically, FIG. 7 shows a plane structure, in which two adjacent solar cells are connected in series to each other, and FIG. 8 is a cross-sectional view taken along line CY2-CY2 of FIG. 7.

Structures and components identical or equivalent to those illustrated in FIGS. 1 to 6 are designated with the same reference numerals, and a further description may be briefly made or may be entirely omitted in FIGS. 7 and 8.

As shown in FIGS. 7 and 8, in the solar cell module according to the embodiment of the invention, first and second solar cells C1 and C2, that are adjacent to each other, may be connected in series to each other through an interconnector IC.

More specifically, as shown in FIG. 7, a plurality of first conductive lines R1 may be connected to a plurality of first electrodes C141 included in each of the first and second solar cells C1 and C2, and a plurality of second conductive lines R2 may be connected to a plurality of second electrodes C142 included in each of the first and second solar cells C1 and C2.

In this instance, each of the plurality of first conductive lines R1 may extend in the second direction y crossing a longitudinal direction of the plurality of first electrodes C141. When viewed from a back surface of a semiconductor substrate 110 as shown in FIG. 7, the plurality of first conductive lines R1 may be connected to the plurality of first electrodes C141, so that the first conductive lines R1 protrude to the outside further than one of both sides of the semiconductor substrate 110 in the first direction x.

Further, each of the plurality of second conductive lines R2 may extend in the second direction y crossing a longitudinal direction of the plurality of second electrodes C142. When viewed from the back surface of the semiconductor substrate 110 as shown in FIG. 7, the plurality of second conductive lines R2 may be connected to the plurality of second electrodes C142, so that the second conductive lines R2 protrude to the outside further than the other of both sides of the semiconductor substrate 110 in the first direction x.

As shown in FIGS. 7 and 8, portions (ones protruding to the outside of the semiconductor substrate 110 of the first solar cell C1) of the plurality of first conductive lines R1 connected to the first solar cell C1 and portions (ones protruding to the outside of the semiconductor substrate 110 of the second solar cell C2) of the plurality of second conductive lines R2 connected to the second solar cell C2 may be connected to a back surface of the interconnector IC. Hence, the plurality of solar cells may be connected in series to form one string.

In the embodiment disclosed herein, the interconnector IC may be disposed in a separation space between the first and second solar cells C1 and C2, namely, a separation space between the semiconductor substrates 110 of the first and second solar cells C1 and C2.

In FIGS. 7 and 8, a conductive adhesive SP may connect the first conductive lines R1 and the interconnector IC and connect the second conductive lines R2 and the interconnector IC.

As shown in FIG. 7, the interconnector IC may have a shape extending in the same direction (i.e., the first direction x) as the longitudinal direction of the first and second electrodes C141 and C142 of the first and second solar cells C1 and C2. As shown in FIG. 8, a thickness of the interconnector IC may be greater than a thickness of the semiconductor substrates 110.

For example, as shown in FIGS. 7 and 8, the interconnector IC according to the embodiment of the invention may be formed as a metal pad extending in the first direction x.

FIGS. 7 and 8 show that the first and second solar cells C1 and C2 are connected in series through the separate interconnector IC, as an example. Unlike this, the first and second conductive lines R1 and R2 may be connected to the electrodes of different conductive types included in the adjacent solar cells to connect the plurality of solar cells in series without separately using the interconnector IC.

Namely, unlike FIGS. 7 and 8, the first conductive line R1 connected to the first electrode C141 of the first solar cell C1 may extend to a back surface of the semiconductor substrate 110 of the second solar cell C2 and may be connected to the second electrode C142 of the second solar cell C2 without separately using the interconnector IC.

Further, the second conductive line R2 connected to the second electrode C142 of the first solar cell C1 may extend to a back surface of a semiconductor substrate 110 of other solar cell, which is positioned adjacent to the first sole cell C1 in the opposite direction of the second solar cell C2 with respect to the first solar cell C1, and may be connected to a first electrode C141 of the other solar cell without separately using the interconnector IC.

As described above, the plurality of solar cells C1 and C2 arranged in the second direction y may be connected in series to each other by the first and second conductive lines R1 and R2 to form one string.

So far, the embodiment of the invention described the structure of the solar cell module. Hereinafter, a method for manufacturing the solar cell module having the above-described structure is described.

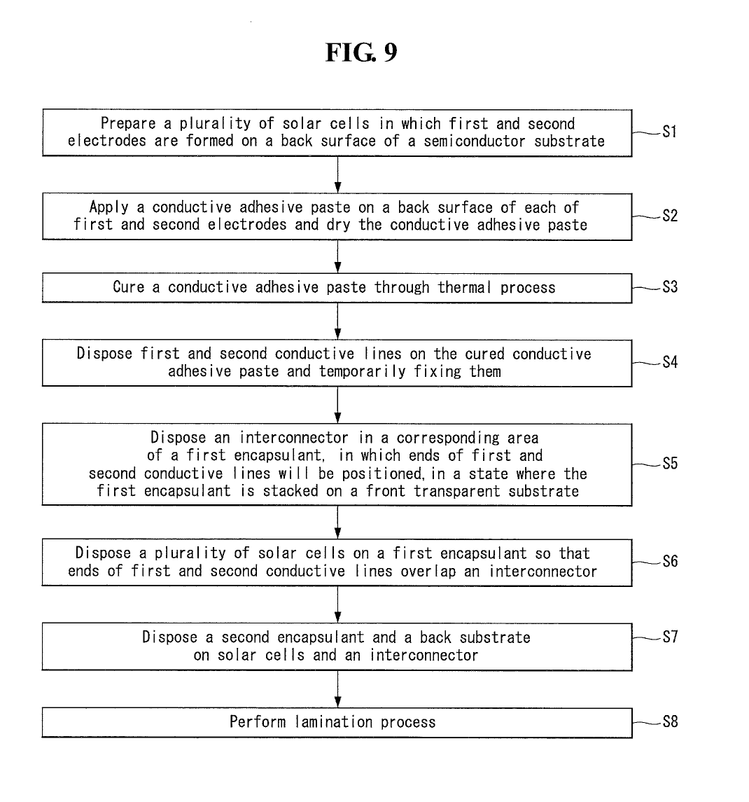

FIG. 9 is a flow chart showing a first example of a method for manufacturing the solar cell module according to the embodiment of the invention.

As shown in FIG. 9, a solar cell, in which first and second electrodes C141 and C142 are formed on a back surface of a semiconductor substrate 110, may be prepared in operation S1.

The solar cell, in which the first and second electrodes C141 and C142 are formed on the back surface of the semiconductor substrate 110, may be substantially the same as the solar cell described above with reference to FIGS. 2 and 3, but is not limited thereto. Any solar cell, in which the first and second electrodes C141 and C142 are formed on the back surface of the semiconductor substrate 110 in one direction, may be used.

Next, an operation S2 of applying a paste for the above-described conductive adhesive SP to a desired portion of a back surface of each of the first and second electrodes C141 and C142 and drying the conductive adhesive paste may be performed.

A viscosity of the conductive adhesive paste in the operation S2 may be greater than a viscosity of a general liquid, for example, water. Thus, the conductive adhesive paste may further include a solvent and a polymer-based binder, in addition to the first, second, and third metal particles PT1, PT2, and PT3 described above with reference to FIG. 6.

In this instance, the viscosity of the conductive adhesive paste may be determined by a ratio of a total amount of the solvent and the binder to a total amount of the first, second, and third metal particles PT1, PT2, and PT3. The total amount of the solvent and the binder included in the conductive adhesive paste according to the embodiment of the invention may be 5 wt % to 15 wt %, and the total amount of the first, second, and third metal particles PT1, PT2, and PT3 included in the conductive adhesive paste may be 85 wt % to 95 wt %.

Hence, the conductive adhesive paste may be maintained at the viscosity much greater than the general liquid, for example, water.

Accordingly, although the conductive adhesive paste is applied on the back surface of each of the first and second electrodes C141 and C142, the conductive adhesive paste is not widely spread or dispersed due to the viscosity and a surface tension of the conductive adhesive paste and may be applied on the first and second electrodes C141 and C142 with a predetermined thickness and a predetermined width.

As a result, the conductive adhesive SP may prevent the adjacent first and second electrodes C141 and C142 from being short-circuited, and the first and second electrodes C141 and C142 may have the shape illustrated in FIGS. 4 to 6.

A process for drying the conductive adhesive paste at a temperature of 80° C. to 120° C. in a state where the conductive adhesive paste is applied may be performed.

In the drying process, the solvent present in the conductive adhesive paste may be evaporated, and thus the conductive adhesive paste may maintain the shape, which is originally obtained when the conductive adhesive paste is applied. FIG. 9 illustrates that the drying process is included in the operation S2, as an example. Unlike this, the drying process may be omitted.

Next, an operation S3 of curing the conductive adhesive paste to form the conductive adhesive SP may be performed. The curing operation S3 may be performed at a thermal processing temperature of 200° C. to 250° C. for about 150 seconds.

In the curing operation S3, the above-described binder may be removed, and surfaces of the first, second, and third metal particles PT1, PT2, and PT3 included in the conductive adhesive paste may be melted and may form intermetallic compounds in the conductive adhesive SP.

When a process time of the curing operation S3 excessively increases, the first metal particles PT1 having the lowest melting point among the first, second, and third metal particles PT1, PT2, and PT3 may be completely melted. In this instance, the conductive adhesive SP may be widely spread or dispersed, and the first and second electrodes C141 and C142 may be short-circuited with each other.

Accordingly, it is preferable, but not required, that the curing operation S3 is performed at the temperature of 200° C. to 250° C. for about 150 seconds. However, when the total amount of the solvent and the binder is changed, the temperature and process time of the curing operation S3 may be changed.

Next, as shown in FIG. 4, an operation S4 of disposing first and second conductive lines R1 and R2 on the cured conductive adhesive SP and temporarily fixing (or bonding) them may be performed.

In the embodiment disclosed herein, the temporarily fixing (or bonding) method may be performed by attaching a transparent tape to the first and second conductive lines R1 and R2 and the back surface of the semiconductor substrate 110 or performing thermal processing using ultrasonic waves or a laser on a local area of each of the first and second conductive lines R1 and R2.

When the temporarily fixing (or bonding) method is performed by performing the thermal processing using the ultrasonic waves or the laser on the local area of each of the first and second conductive lines R1 and R2, only coating layers RSC of the first and second conductive lines R1 and R2 having a melting point lower than a melting point of the conductive adhesive SP may be melted, and thus the first and second conductive lines R1 and R2 may be temporarily fixed (or bonded) to the conductive adhesive SP. Hence, the first and second conductive lines R1 and R2 may be temporarily fixed to the back surface of the solar cell.

In other words, as shown in FIGS. 4 and 5, the first and second conductive lines R1 and R2 may be temporarily fixed to the back surface of the semiconductor substrate 110.

The above-described temporarily fixing method may be omitted. However, when the temporarily fixing method is used, the manufacturing process of the solar cell module may be more easily performed.

Next, in an operation S5, a front transparent substrate FS may be disposed so that its front surface faces downwardly, and a first encapsulant EC1 may be disposed on a back surface of the front transparent substrate FS. In this instance, the first encapsulant EC1 may have a sheet shape.

In the operation S5, an interconnector IC may be disposed on a corresponding area of the first encapsulant EC1, in which an end of each of the first and second conductive lines R1 and R2 temporarily fixed to each solar cell will be positioned, in a state where the front transparent substrate FS and the first encapsulant EC1 are stacked.

Next, in an operation S6, the plurality of solar cells may be positioned on the first encapsulant EC1, so that the end of each of the first and second conductive lines R1 and R2 temporarily fixed to the back surface of each solar cell overlaps the interconnector IC. In this instance, each solar cell may be disposed, so that its front surface faces toward the first encapsulant EC1.

In this instance, a disposition configuration of the first and second conductive lines R1 and R2 temporarily fixed to the back surface of the semiconductor substrate 110 of each solar cell and the interconnector IC may be substantially the same as the disposition configuration shown in FIG. 7.

Next, in an operation S7, a second encapsulant EC2 and a back substrate BS may be disposed on the solar cells and the interconnector IC. In this instance, the second encapsulant EC2 may have a sheet type.

Next, a lamination process may be performed in operation S8. The lamination process may involve an exhaust process for removing an air between the front transparent substrate FS and the back substrate BS, a pressurization process, and/or a thermal process.

A thermal processing temperature in the lamination operation S8 may be lower than the thermal processing temperature in the operation S3 of curing the conductive adhesive paste, so that the conductive adhesive cured during the lamination process is not melted.

For example, a maximum value of the thermal processing temperature in the lamination operation S8 may be 150° C. to 160° C.

The thermal process in the lamination operation S8 may have a profile, in which the thermal processing temperature increases up to the highest temperature, is maintained at the highest temperature for a predetermined period of time, and falls.

When the thermal processing temperature in the lamination operation S8 increases and reaches about 70° C. to 100° C., the first and second encapsulants EC1 and EC2 each having the sheet shape may be melted. Then, the first encapsulant EC1 may be attached to the front surface of the semiconductor substrate 110 of each solar cell through the exhaust process and the pressurization process of the lamination operation S8, and the second encapsulant EC2 may be attached to the back surface of the semiconductor substrate 110 of each solar cell through the exhaust process and the pressurization process of the lamination operation S8.

In this instance, when the second encapsulant EC2 is attached to the back surface of the semiconductor substrate 110 of each solar cell, the second encapsulant EC2 may be filled in a separation space between the first conductive line R1 and the second electrode C142, a separation space between the second conductive line R2 and the first electrode C141, and a space between the first electrode C141 and the second electrode C142.

Subsequently, when the thermal processing temperature in the lamination operation S8 increases up to the highest temperature of 150° C. to 160° C., the coating layers RSC of the first and second conductive lines R1 and R2 may be melted and attached to the conductive adhesive SP.

In this instance, because the melting point of the conductive adhesive SP is higher than the thermal processing highest temperature (i.e., 150° C. to 160° C.) in the lamination operation S8, the conductive adhesive SP is not melted in the lamination operation S8 and may maintain a thickness, which has been obtained before the lamination operation S8.

Further, because the coating layer RSC and the conductive adhesive SP include the same metal material, i.e., tin (Sn), a contact resistance therebetween may greatly decrease.

Hence, the solar cell module illustrated in FIGS. 1 to 8 may be completed.

As described above, the solar cell module according to the embodiment of the invention does not have to include a separate insulating layer for preventing a short circuit between the first conductive line R1 and the second electrode C142 and a short circuit between the second conductive line R2 and the first electrode C141, and thus can further simplify the manufacturing process.

FIG. 9 illustrates the method for manufacturing the solar cell module, in which the interconnector is positioned between the solar cells, as an example. The embodiment of the invention is not limited thereto and may be applied to the solar cell module, in which the interconnector is omitted. This is described in detail below.

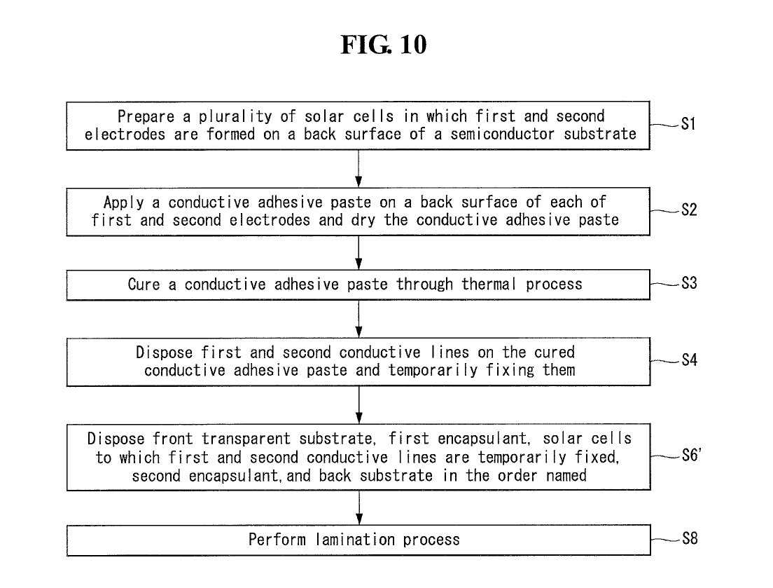

FIG. 10 is a flow chart showing a second example of a method for manufacturing the solar cell module according to the embodiment of the invention.

As shown in FIG. 10, the second example of the method for manufacturing the solar cell module according to the embodiment of the invention may include an operation S1 of preparing solar cells, an operation S2 of applying and drying a conductive adhesive paste, an operation S3 of curing the conductive adhesive paste through a thermal process, an operation S4 of disposing and temporarily fixing first and second conductive lines, a disposition operation S6′, and a lamination operation S8.

The second example of the method for manufacturing the solar cell module not including the separate interconnector according to the embodiment of the invention may be very similar to the first example of the manufacturing method illustrated in FIG. 9.

More specifically, the operation S1 of preparing the solar cells, the operation S2 of applying and drying the conductive adhesive paste, the operation S3 of curing the conductive adhesive paste through the thermal process, the operation S4 of disposing and temporarily fixing the first and second conductive lines, and the lamination operation S8, which are described in the first example of the manufacturing method of FIG. 9, may be applied to the second example of the manufacturing method illustrated in FIG. 10.

Because the solar cell module according to the second example of the manufacturing method does not include the separate interconnector IC, the first conductive line R1 temporarily bonded to the first electrode C141 of the first solar cell C1 may be temporarily bonded to the second electrode C142 of the second solar cell C2 in the operation S4 of disposing and temporarily fixing the first and second conductive lines in the second example of the manufacturing method.

Hence, in the operation S4 of disposing and temporarily fixing the first and second conductive lines, the plurality of solar cells may be connected in series by the first and second conductive lines R1 and R2.

In the disposition operation S6′ of the second example of the manufacturing method, the front transparent substrate FS, the first encapsulant EC1, the first and second solar cells C1 and C2 to which the first and second conductive lines R1 and R2 are temporarily fixed and which are connected in series to each other, the second encapsulant EC2, and the back substrate BS may be stacked and disposed in the order named.

Hence, the front transparent substrate FS may be disposed on the front surface of each solar cell, the back substrate BS may be disposed on the back surface of each solar cell, the first encapsulant EC1 may be disposed between the front transparent substrate FS and the first and second solar cells C1 and C2, and the second encapsulant EC2 may be disposed between the back substrate BS and the first and second solar cells C1 and C2.

The foregoing embodiments are merely example and are not to be considered as limiting the present disclosure. The present teachings can be readily applied to other types of methods and apparatuses. This description is intended to be illustrative, and not to limit the scope of the claims. Many alternatives, modifications, and variations will be apparent to those skilled in the art. The features, structures, methods, and other characteristics of the example embodiments described herein may be combined in various ways to obtain additional and/or alternative example embodiments.

As the present features may be embodied in several forms without departing from the characteristics thereof, it should also be understood that the above-described embodiments are not limited by any of the details of the foregoing description, unless otherwise specified, but rather should be considered broadly within its scope as defined in the appended claims, and therefore all changes and modifications that fall within the metes and bounds of the claims, or equivalents of such metes and bounds, are therefore intended to be embraced by the appended claims.

What is claimed is:

1. A solar cell module comprising:
a front transparent substrate and a back substrate positioned opposite each other;
a plurality of solar cells positioned between the front transparent substrate and the back substrate, each solar cell including a semiconductor substrate and first and second electrodes, the first and second electrodes being separated from each other on a back surface of the semiconductor substrate and each extending in a first direction;
a first conductive line connected to the first electrode included in the each solar cell through a conductive adhesive;
a second conductive line connected to the second electrode included in the each solar cell through the conductive adhesive;
a first encapsulant of an insulating material positioned between the plurality of solar cells and the front transparent substrate; and
a second encapsulant of an insulating material positioned between the plurality of solar cells and the back substrate,
wherein the second encapsulant is filled in a space between the first electrode of the each solar cell and the second conductive line and a space between the second electrode of the each solar cell and the first conductive line.

2. The solar cell module of claim 1, wherein the second encapsulant is further filled in a space between the first electrode and the second electrode in the each solar cell.

3. The solar cell module of claim 1, wherein the first and second conductive lines are separated from each other and each of the first and second conductive lines extends in a second direction crossing the first direction.

4. The solar cell module of claim 1, wherein a thickness of the conductive adhesive is greater than a thickness of each of the first and second electrodes.

5. The solar cell module of claim 4, wherein a thickness of each of the first and second conductive lines is greater than the thickness of the conductive adhesive.

6. The solar cell module of claim 4, wherein the thickness of the each of the first and second electrodes is 0.2 μm to 1 μm.

7. The solar cell module of claim 4, wherein the thickness of the conductive adhesive is 50 μm to 150 μm.

8. The solar cell module of claim 5, wherein the thickness of the each of the first and second conductive lines is 180 μm to 220 μm.

9. The solar cell module of claim 1, wherein each of the first and second conductive lines includes a core and a coating layer coated on a surface of the core, and
wherein a melting point of the coating layer is lower than a melting point of the core.

10. The solar cell module of claim 9, wherein the conductive adhesive includes metal particles having a melting point that is higher than the melting point of the coating layer and is lower than the melting point of the core.

11. The solar cell module of claim 10, wherein the metal particles include first metal particles having a melting point higher than 160° C.

12. The solar cell module of claim 11, wherein the metal particles include second metal particles having a melting point higher than the melting point of the first metal particles.

13. The solar cell module of claim 12, wherein an amount of the first metal particles is greater than an amount of the second metal particles.

14. The solar cell module of claim 12, wherein the conductive adhesive includes an intermetallic compound, that is chemically bonded by melting surfaces of the first and second metal particles, between the first and second metal particles.

15. The solar cell module of claim 9, wherein the melting point of the coating layer is 110° C. to 160° C.

16. The solar cell module of claim 1, wherein a melting point of the second encapsulant is 70° C. to 100° C.

17. The solar cell module of claim 1, wherein the second encapsulant includes at least one of ethylene vinyl acetate (EVA), polyolefin, ionomer, or poly vinyl butyral (PVB).

18. The solar cell module of claim 1, wherein the plurality of solar cells include a first solar cell and a second solar cell, and
wherein a first conductive line connected to a first electrode of the first solar cell and a second conductive line connected to a second electrode of the second solar cell are positioned between semiconductor substrates of the first and second solar cells and are connected to an interconnector extending in the first direction.

19. A method for manufacturing a solar cell module, the method comprising:
preparing a solar cell, in which first and second electrodes are formed on a back surface of a semiconductor substrate of the solar cell;
a conductive adhesive forming operation of applying a conductive adhesive paste on each of the first and second electrodes and curing the conductive adhesive paste through thermal processing to form a conductive adhesive;
temporarily bonding a first conductive line including a coating layer having a melting point lower than a melting point of the cured conductive adhesive to the first electrode and temporarily bonding a second conductive line including a coating layer having a melting point lower than a melting point of the cured conductive adhesive to the second electrode;
a disposition operation of disposing a front transparent substrate on a front surface of the solar cell, disposing a back substrate on a back surface of the solar cell, disposing a first encapsulant between the front transparent substrate and the solar cell, and disposing a second encapsulant between the back substrate and the solar cell; and
a lamination operation of, after the disposition operation, performing a pressurization process and a thermal process to fill the second encapsulant between the first and second electrodes.

20. The method of claim 19, wherein the lamination operation includes filling the second encapsulant between the first electrode and the second conductive line and between the second electrode and the first conductive line.

21. The method of claim 19, wherein the solar cell includes a first solar cell and a second solar cell, the method further comprising disposing an interconnector between the first solar cell and the second solar cell that are positioned adjacent to each other, a first conductive line connected to the first solar cell and a second conductive line connected to the second solar cell being commonly connected to the interconnector.

22. The method of claim 19, wherein a temperature of the thermal processing in the conductive adhesive forming operation is higher than a temperature of the thermal process in the lamination operation.
